(19) United States
(12) Patent Application Publication
(10) Pub. No.: US 2009/0273088 A1
(43) Pub. Date: Nov. 5, 2009

(54) Semiconductor Device and Method for Fabricating the Same

(75) Inventors: Sung Woong Chung, Icheon-si (KR); Sang Min Hwang, Seoul (KR); Hyun Jung Kim, Seoul (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/265,894

(22) Filed: Nov. 6, 2008

(30) Foreign Application Priority Data
May 2, 2008 (KR) 10-2008-0041442

(51) Int. Cl. H01L 23/535; H01L 21/768

(52) U.S. Cl. 257/773; 438/666; 257/E23.168; 257/E21.585

(57) ABSTRACT

A method for fabricating a semiconductor device includes forming a metal word line additionally over a vertical transistor to obtain a multi-layered structure, thereby preventing degradation of the operating speed of the semiconductor device by preventing an increase of resistance of a damascene word line that connects a surrounding gate of a vertical transistor. As a result, the yield and reliability of the semiconductor device can be improved.

The priority benefit of Korean patent application number 10-2008-0041442, filed on May 2, 2008, is hereby claimed and the disclosure thereof is incorporated herein by reference in its entirety.

### BACKGROUND OF THE INVENTION

Semiconductor devices such as DRAM have required including many transistors in a limited region so as to improve integration. Accordingly, a vertical transistor as a element included in high integrated memory cell generally having an area of 4 F² has been suggested. The vertical transistor has a surrounding gate structure that surrounds a vertical channel.

In order to form the surrounding gate in area 4 F² area, a channel region is selectively isotropic-etched so that the channel region is formed to be thinner than the source/drain regions, thereby obtaining excellent device characteristics. As a result, the vertical transistor can use a limited area effectively. Furthermore, the vertical transistor has been spotlighted in various fields with DRAMs because of the ability to manufacture the smaller-sized transistors.

The vertical transistor may maintain a given channel length even when a device area is reduced, so that the vertical transistor is efficient in a short channel effect (SCE). Specifically, the surrounding gate can maximize gate controllability to improve the SCE, and have a large current flowing area to provide excellent operating current characteristics. To accomplish these goals, the vertical transistor is required to have a thin and long structure so as to increase integration. The surrounding gate of the vertical transistor includes a doped poly silicon (Si) for reliability of a gate insulating film. Also, as the thickness of the vertical transistor becomes thinner, the thickness of the gate electrode becomes thinner increasing resistance of the surrounding gate.

The surrounding gate is connected to a damascene word line in which sidewalls of the surrounding gate are connected, thereby increasing resistance of the word line. The increase of resistance lowers the operating speed of the semiconductor device. As a result, the number of cells that can be operated by one word line is reduced.

FIG. 1 is a top view illustrating a conventional method for fabricating a semiconductor device. The conventional method for fabricating a semiconductor device includes providing a semiconductor substrate 100, a vertical transistor channel 115, a gate electrode 120, a bit line 130, a word line 150, a contact plug 185, and a conductive line 195.

The semiconductor substrate 100 is etched to form the vertical transistor 115. A gate electrode 120 that surrounds the channel 115 is formed. A buried bit line 130 is formed in the bottom of the vertical transistor. The gate electrodes 120 that surround the vertical transistor are electrically connected through the word line 150.

The word line 150 is connected through from the edge of the cell region to a contact plug (not shown) and a conductive line (not shown) of a peripheral circuit region (not shown) so as to receive an operating voltage. The bottom bit line 130 is connected through the contact plug 185 and the conductive line 195 of a sense amplifier region 1000 so as to receive and transmit a signal.

FIGS. 2 and 3 are cross-sectional views illustrating the semiconductor device shown in FIG. 1. A cross-section taken along X-X′ of FIG. 1, and FIG. 3 shows a cross-section taken along Y-Y′ of FIG. 1, the semiconductor substrate 100 is etched to form the vertical transistor channel 115. The gate electrode 120 that surrounds the vertical transistor channel 115 is formed.

The bit line 130 buried in the bottom of the vertical transistor is formed, and an insulating film 140 for separating the buried bit line 130 is formed. The word line 150 for connecting the gate electrodes 120 that surround the vertical transistor is formed. After interlayer insulating films 160 and 170 are formed over the resulting structure, The interlayer insulating films 160 and 170 are etched to form cell plugs 165 and 175 connected to the vertical transistor channel 115.

The insulating film 140, the interlayer insulating films 160 and 170 are etched to form a contact hole (not shown) that exposes an end portion of the buried bit line 130. A plug material is buried in a contact hole (not shown) to form a contact plug 185. The contact plug 185 is connected to the conductive line 195 over the sense amplifier region.

As mentioned above, the semiconductor device that includes a vertical transistor has a structure where a voltage of the word line is transmitted through the surrounding gate (gate electrode). However, since the surrounding gate includes a polysilicon layer, the structure through which a voltage of the word line is transmitted, the surrounding gate has a high resistance to lower the signal speed of the word line. As a result, the number of cells that can be operated by one word line is reduced.

### SUMMARY OF THE INVENTION

Various embodiments of the present invention are directed at providing a method for fabricating a semiconductor device that may include forming a metal word line additionally over a vertical transistor to obtain a multi-layered structure, thereby preventing degradation of the operating speed of the semiconductor device due to an increase of resistance of a damascene word line that connects a surrounding gate of a vertical transistor. As a result, the yield and reliability of the semiconductor device can be improved.

According to an embodiment of the present invention, a semiconductor device may include: a plurality of first word lines connected a gate of a vertical transistor in a given number unit; and a second word line configured to supply a gate power to the first word lines.

In the semiconductor device, one end of the first word line may be formed to have a pad type. The second word line may be formed to be parallel to the first word line over the first word line. The second word line may include a metal line.

The semiconductor device may further include a contact plug configured to connect the second word line to the first word line. The contact plug may be formed in one end of the first word line.

According to an embodiment of the present invention, a method for fabricating a semiconductor device may include: forming a vertical transistor over a semiconductor substrate; forming a bit line in the bottom of the vertical transistor; forming first word lines configured to connect a gate of the vertical transistor in a given number unit perpendicular to the bit line; forming an interlayer insulating film over the vertical transistor; etching a portion of the interlayer insulating film to form a contact hole that exposes one end of the first word line; and filling a plug material in the contact hole to form a contact plug and forming a second word line connected to the contact plug and arranged parallel to the first word line.

In the method, one end of the first word line may be formed to have a pad type. The second word line may be formed to be parallel to the first word line over the first word line. The second word line may be formed when a gate electrode of a peripheral circuit region is formed. The second word line may be formed when a bit line electrode of the peripheral circuit region is formed.

The method further may include forming a storage node contact plug connected to the top portion of the vertical transistor between the second word lines. The storage node contact plug may be formed by a self-align contact process using the second word line.

### BRIEF DESCRIPTION OF THE DRAWINGS

FIG. 1 is a top view illustrating a conventional method for fabricating a semiconductor device.

FIGS. 2 and 3 are cross-sectional views illustrating a conventional semiconductor device.

FIG. 4 is a diagram illustrating a semiconductor device according to an embodiment of the present invention.

FIG. 5 is a top view illustrating a method for fabricating a semiconductor device according to an embodiment of the present invention.

FIGS. 6 and 7 are cross-sectional views illustrating a semiconductor device according to an embodiment of the present invention.

FIG. 8 is a circuit diagram illustrating a semiconductor device according to an embodiment of the present invention.

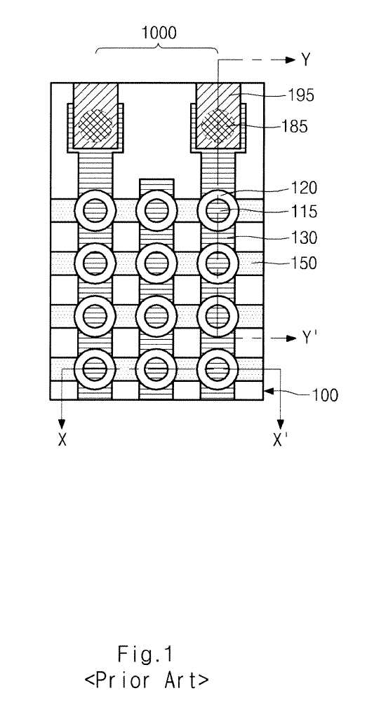

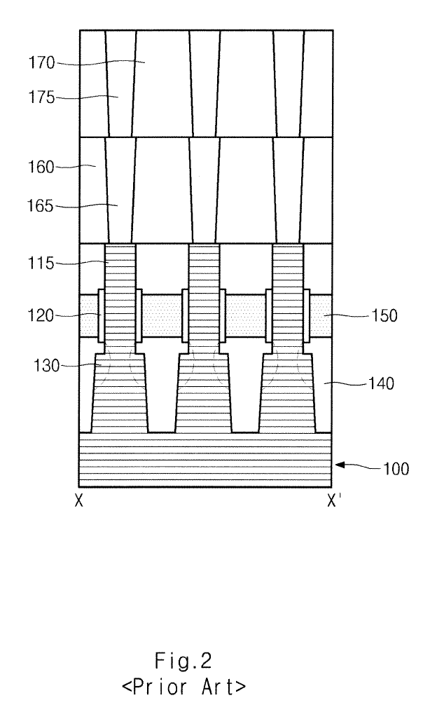

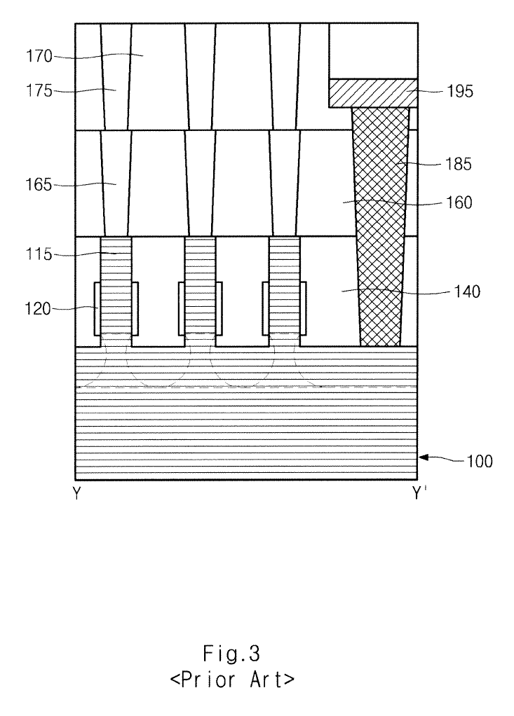

### DETAILED DESCRIPTION OF SPECIFIC EMBODIMENT

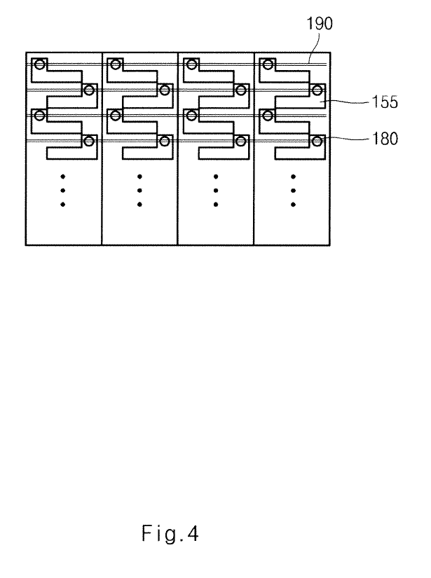

FIG. 4 is a diagram illustrating a semiconductor device according to an embodiment of the present invention.

The semiconductor device of FIG. 4 includes a plurality of word lines 155 configured to electrically connect surrounding gates of a vertical transistor in a given number unit and a second word line 190 arranged parallel to the first word lines over the first word lines and configured to supply a gate voltage to the first word lines 155. The second word line 190 is connected to the first word lines 155, which are electrically connected to the second word line 190 through a contact plug 180. The second word line 190 includes a metal line having an excellent conductivity. The second word line 190 receives a gate power from a peripheral circuit region and provides the gate power to the first word lines 155.

As can be seen, the gate voltage from the peripheral circuit region is not directly applied to the damascene. Instead, the gate voltage is supplied to the first word lines 155 through the second word line 190 having an excellent conductivity. Each surrounding gate can receive the gate voltage simultaneously regardless of the distance or the time from the peripheral circuit region.

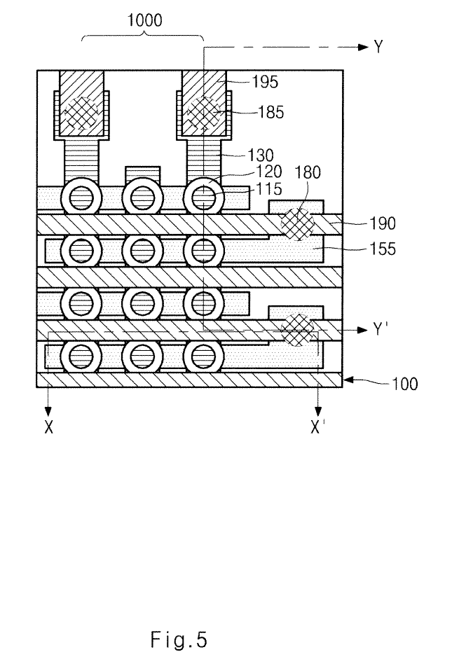

FIG. 5 is a top view illustrating a method for fabricating a semiconductor device according to an embodiment of the present invention. FIG. 5 shows an enlarged view of a part of the semiconductor device of FIG. 4.

The semiconductor device shown in FIG. 5 includes a semiconductor substrate 100, a vertical transistor channel 115, a gate electrode 120, a bit line 130, a first word line 155, contact plugs 180, 185, a second word line 190 and a conductive line 195. The semiconductor substrate 100 is etched to form a vertical transistor channel 115. A gate electrode 120 surrounds the channel 115.

A buried bit line 130 is formed in the bottom of the vertical transistor. The gate electrodes 120 that surround the vertical transistor are electrically connected through the first word lines 155 in a given number unit. One end of the first word line 155 is formed to have a pad type so as to form a contact plug 180 connected with the second word line 190.

A metal line, which is a power supply path from the peripheral circuit region (not shown), is extended to a cell region toward the same direction as the damascene word line to form the second word line 190. The second word line 190 is connected to the first word lines 155 through the contact plug 180. The bottom bit line 130 is connected through the conductive line 195 and the contact plug 185 of a sense amplifier region 1000 so as to transmit and receive a signal or data.

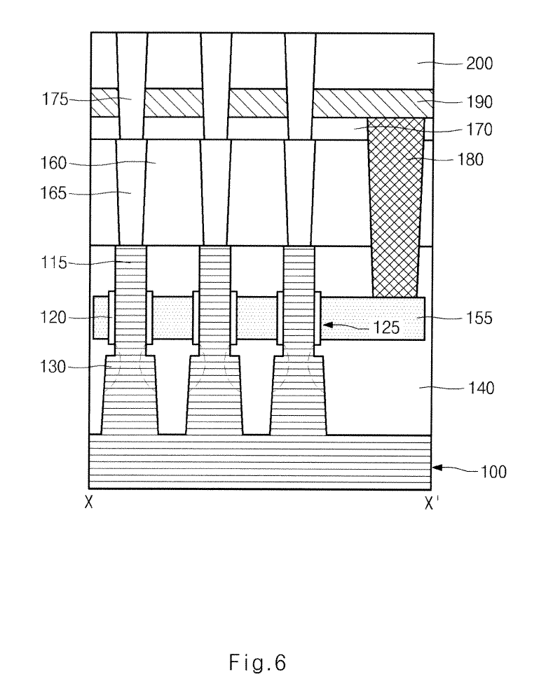

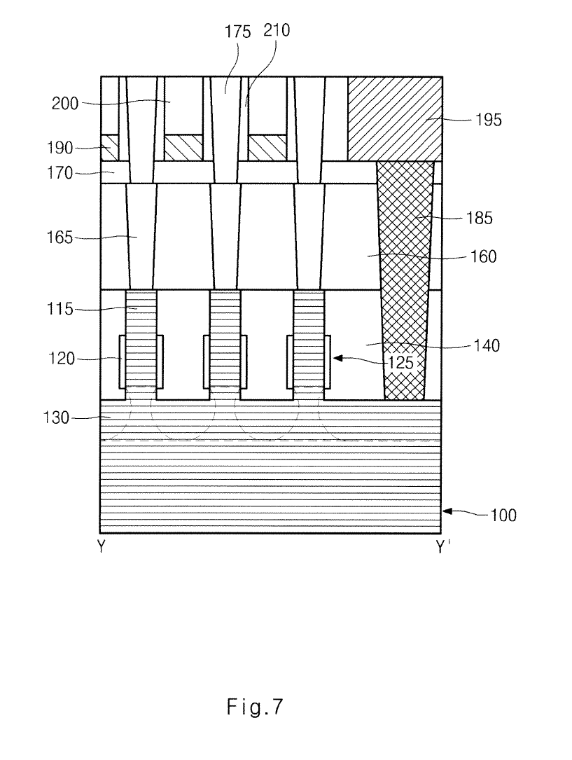

FIGS. 6 and 7 are cross-sectional views illustrating a semiconductor device according to an embodiment of the present invention. FIG. 6 shows a cross-section taken along X-X′ of FIG. 5, and FIG. 7 shows a cross-section taken along Y-Y′ of FIG. 5.

Referring to FIGS. 6 and 7, the semiconductor substrate 100 is etched to form the vertical transistor 115. A gate electrode 120 that surrounds the vertical transistor channel 115 is formed.

After the bit line 130 buried in the bottom of the vertical transistor is formed, an insulating film 140 for separating the buried bit line 130 is formed. The first word line 155 for connecting the gate electrode 120 that surrounds the vertical transistor is formed.

After interlayer insulating films 160 and 170 are formed over the resulting structure, the interlayer insulating films 160 and 170 are etched to form storage node contact plugs 165 and 175, which are connected with the vertical transistor channel 115.

A portion of the interlayer insulating films 160 and 170 is etched to form a contact hole (not shown) that exposes the first word line 155. A plug material is filled in the contact hole (not shown) to form a contact plug 180. The contact plug is formed at one end of the first word line 155. The one end of the first word line 155 is formed to have a pad type.

A metal line, that is, a second word line 190, is formed between the storage node plugs 175. The second word line 190 is formed in parallel with the first word line 155 over the first word line 155 not to be overlapped with each other. The second word line 190 is formed simultaneously when the gate electrode of the peripheral circuit region (not shown) or when a bit line electrode of the peripheral circuit region is formed. The storage node contact plug 175 that is connected to the top portion of the vertical transistor is formed between the second word lines 190.

The storage node contact plug 175 is formed by a self-align contact process using the second word line 190. After interlayer insulating films 200 and 210 are formed over the resulting structure, each storage node contact plug 175 is insulated.

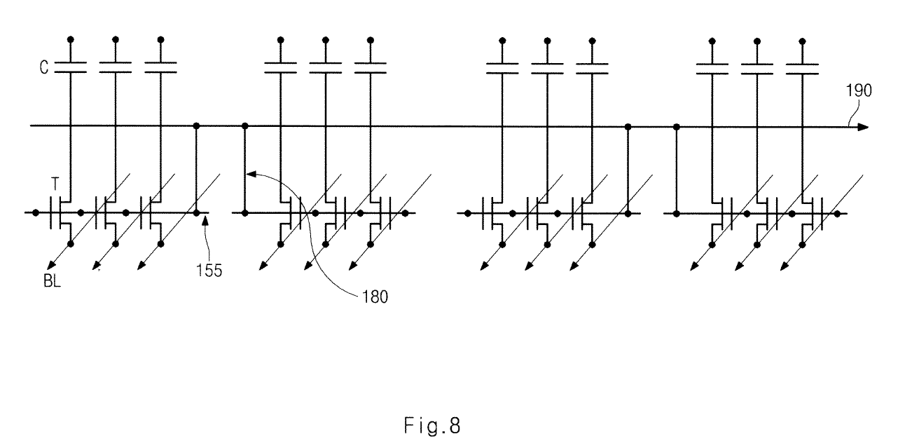

FIG. 8 is a circuit diagram illustrating the relation between the first word line and the second word line according to an embodiment of the present invention. A circuit includes a plurality of first word lines 155 for electrically connecting gates of the vertical transistor in a given number unit and the second word lines 190 for supplying a gate voltage. The plurality of first word lines 155 corresponding to one second word line 190 are connected electrically to the second word line 190 through the contact plug 180.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or nonvolatile memory device. Other additions, subtractions, or modifications are obvious in view of the present disclosure and are intended to fall within the scope of the appended claims.

What is claimed is:

1. A semiconductor device comprising:
a plurality of first word lines connected to a gate of a vertical transistor in a given number unit; and
a second word line configured to supply a gate power to the first word lines.

2. The semiconductor device according to claim 1, wherein one end of the first word line is formed to have a pad type.

3. The semiconductor device according to claim 1, wherein the second word line is formed to be parallel to the first word line over the first word line.

4. The semiconductor device according to claim 1, wherein the second word line includes a metal line.

5. The semiconductor device according to claim 1, further comprising a contact plug configured to connect the second word line to the first word line.

6. The semiconductor device according to claim 5, wherein the contact plug is formed in one end of the first word line.

7. A method for fabricating a semiconductor device, the method comprising:
forming a vertical transistor over a semiconductor substrate;
forming a bit line in the bottom of the vertical transistor;
forming first word lines configured to connect a gate of the vertical transistor in a given number unit perpendicular to the bit line;
forming an interlayer insulating film over the vertical transistor;
etching a portion of the interlayer insulating film to form a contact hole that exposes one end of the first word line; and
filling a plug material in the contact hole to form a contact plug and forming a second word line connected to the contact plug and arranged parallel to the first word line.

8. The method according to claim 7, wherein one end of the first word line is formed to have a pad type.

9. The method according to claim 7, comprising forming the second word line includes a metal line.

10. The method according to claim 7, comprising forming the second word line when forming a gate electrode of a peripheral circuit region.

11. The method according to claim 7, comprising forming the second word line when forming a bit line electrode of the peripheral circuit region.

12. The method according to claim 7, further comprising forming a storage node contact plug connected to the top portion of the vertical transistor between the second word lines.

13. The method according to claim 12, comprising forming the storage node contact plug by a self-align contact process using the second word line.
